(19) United States
(12) Patent Application Publication
(10) Pub. No.: US 2011/0281440 A1
(43) Pub. Date: Nov. 17, 2011

(54) METHODS FOR NITRIDATION AND OXIDATION

(76) Inventor: Peter Porshnev, Santa Clara, CA (US)

(21) Appl. No.: 13/191,167

(22) Filed: Jul. 26, 2011

Related U.S. Application Data
(62) Division of application No. 13/017,904, filed on Jan. 31, 2011.
(60) Provisional application No. 61/300,586, filed on Feb. 2, 2010.

(51) Int. Cl. H01L 21/263; H01L 21/3105

(52) U.S. Cl. 438/762; 438/765; 257/E21.333; 257/E21.241

(57) ABSTRACT

Methods of nitridation and selective oxidation are provided herein. In some embodiments, a method of selectively forming an oxide layer on a semiconductor structure disposed on a substrate support in a process chamber is provided, wherein the semiconductor structure comprising a substrate, one or more metal-containing layers, and one or more non metal-containing layers. The method may include forming a first remote plasma from a first process gas comprising oxygen; and exposing the semiconductor structure to a reactive species formed from the first remote plasma to selectively form an oxide layer on the one or more non metal-containing layers, wherein a density of the reactive species is about 10⁹ to about 10¹⁷ molecules/cm³ and wherein a pressure in the chamber during exposure of the first layer is about 5 mTorr to about 3 Torr.

### CROSS-REFERENCE TO RELATED APPLICATIONS

This application is a divisional of co-pending U.S. patent application Ser. No. 13/017,904, filed Jan. 31, 2011, which claims benefit of U.S. provisional patent application Ser. No. 61/300,586, filed Feb. 2, 2010. Each of the aforementioned related patent applications is herein incorporated by reference.

### BACKGROUND

1. Field

Embodiments of the present invention generally relate to semiconductor processing methods, and particularly to methods for nitridation and oxidation.

2. Description of the Related Art

Decoupled plasma nitridation (DPN) may be used, for example, to incorporate nitrogen into a gate dielectric layer. For example, nitrogen can be incorporated into a silicon oxide (SiO₂) gate dielectric layer to form silicon oxynitride (SiON). The challenge with decoupled plasma nitridation has been to avoid excess nitrogen at, for example, an interface between the gate dielectric layer and a silicon gate. Typically, this challenge has been addressed by switching plasma generation from a continuous wave (CW) mode to a pulsed RF mode. Thus, the process throughput is slowed due to the pulsed RF mode. Moreover, a reduction in RF power in an attempt to improve the duty cycle can result in a plasma density that is insufficient for nitridation. Further, while the nitridation rate can be reduced by increasing chamber pressure, in-situ plasma provided by a decoupled plasma source is non-uniform at high chamber pressure.

Thus, the inventor has provided improved methods for nitridation that provide a process window sufficient for increased process throughput. The inventor has also discovered that similar techniques may be used to provide improved methods for selective oxidation of a substrate.

### SUMMARY

Methods of nitridation and selective oxidation are provided herein. In some embodiments, a method of nitridation includes providing a substrate having a first layer disposed thereon, where the substrate is disposed on a substrate support in a process chamber; forming a remote plasma from a process gas comprising nitrogen; and exposing the first layer to a reactive species formed from the remote plasma to form a nitrogen-containing layer, wherein a density of the reactive species is about 10⁹ to about 10¹⁷ molecules/cm³ and wherein a pressure in the chamber during exposure of the first layer is about 5 mTorr to about 3 Torr. In some embodiments, the nitrogen-containing layer may be a gate dielectric layer for use in a semiconductor device.

A method of selective oxidation includes providing a semiconductor structure comprising a substrate, one or more metal-containing layers, and one or more non metal-containing layer; placing the structure on a substrate support in a process chamber; forming a first remote plasma from a first process gas comprising oxygen; and exposing the semiconductor structure to a reactive species formed from the first remote plasma to selectively form an oxide layer on the one or more non metal-containing layers, wherein a density of the reactive species is about 10⁹ to about 10¹⁷ molecules/cm³ and wherein a pressure in the chamber during exposure of the first layer is about 5 mTorr to about 3 Torr.

In some embodiments, the semiconductor structure includes the substrate having a tunnel oxide layer, a floating gate layer, one or more electrically conductive barrier layers, one or more metal layers, and a capping layer disposed thereon. In some embodiments, the oxide layer may be selectively formed on a side wall of the tunnel oxide layer and the floating gate layer. In some embodiments, the tunnel oxide layer may also contain nitrogen and may be formed using the method of nitridation described above. Other embodiments and variations of the present invention are disclosed below.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart of a nitridation process in accordance with some embodiments of the present invention.

FIGS. 2A-C illustrate stages of fabrication of a semiconductor structure in accordance with some embodiments of the nitridation process in FIG. 1.

FIG. 3 depicts a flow chart of an oxidation process in accordance with some embodiments of the present invention.

FIGS. 4A-B illustrate stages of fabrication of a semiconductor structure in accordance with some embodiments of the oxidation process in FIG. 3.

FIG. 5 illustrates a remote plasma reactor suitable for carrying out embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide methods for nitridation and selective oxidation of semiconductor structures. The inventive processes advantageously provide nitridation and oxidation using reactive species at higher densities, pressures, and temperatures than conventional plasma processes can provide, thereby facilitating increase throughput as compared to conventional in-situ plasma processes.

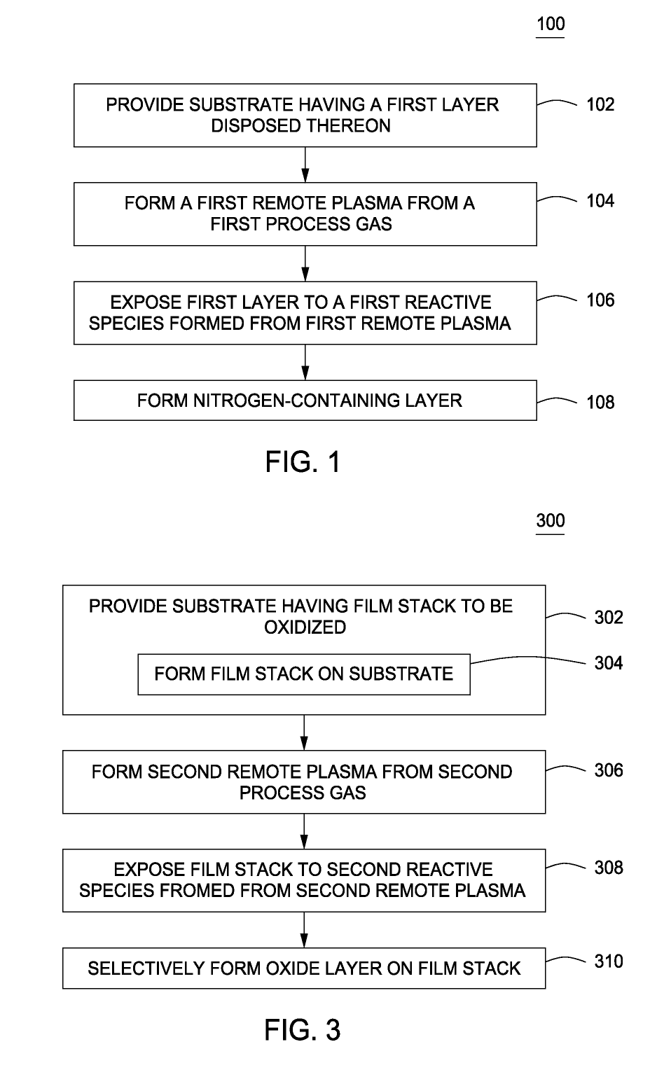

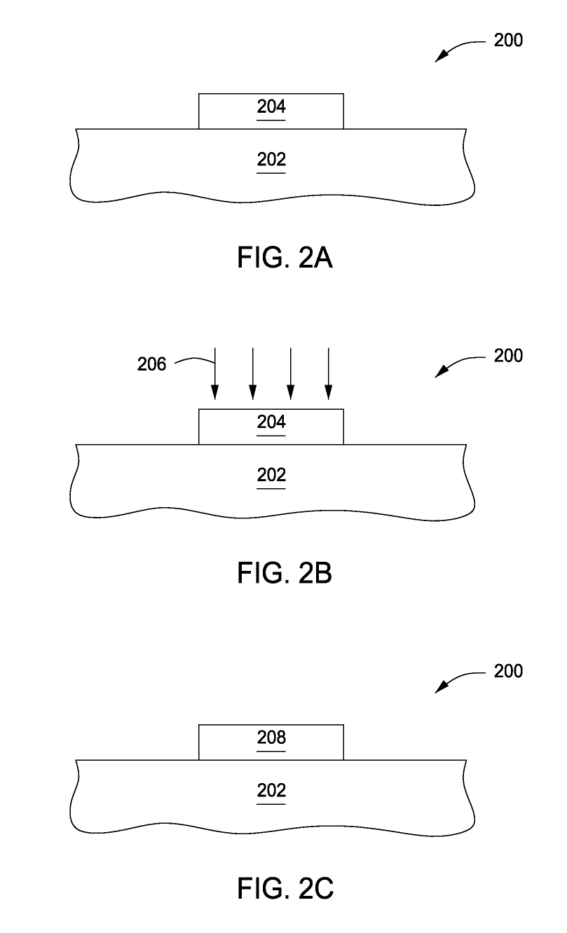

FIG. 1 depicts a nitridation process 100 for forming an nitrogen-containing layer in accordance with some embodiments of the present invention. The process 100 is described herein with respect to the illustrative semiconductor structure depicted in FIGS. 2A-C, which respectively depict stages of fabrication of a semiconductor structure. The process 100 may be performed, for example, in a toroidal source plasma immersion ion implantation reactor (e.g., a remote plasma reactor) such as the remote plasma reactor depicted in FIG. 3. The toroidal source plasma reactor may be capable of providing a larger process window, such as higher plasma densities, process temperatures, chamber pressures, and the like, than conventional in-situ inductively coupled or capacitively coupled plasma reactors. For example, the inventor has discovered that higher plasma densities, when provided remotely, can facilitate improved throughput for both nitridation and oxidation processes. Although a toroidal source plasma reactor is described in the present application, it is contemplated that other suitable remote plasma reactors may be used to perform the inventive methods. Such remote plasma sources include, but are not limited to, one of the Astron® line, available from MKS Instruments of Andover, Mass. Other plasma chambers can be used in combination with remote plasma sources to enable this process. Such plasma chambers include, but are not limited to, High Density Plasma Chemical Vapor Deposition (HDPCVD), Plasma Enhanced Chemical Vapor Deposition (PECVD) or Decoupled Plasma Nitridation (DPN) chambers available from Applied Materials, Inc., of Santa Clara, Calif. It is contemplated that other plasma chambers having non-remote plasma sources may also be utilized if modified to provide the beneficial plasma characteristics described below.

The process 100 begins at 102, where a semiconductor device 200 is provided. The semiconductor device 200 may include a substrate 202 having a first layer 204 to be nitridized disposed thereupon, as shown in FIG. 2A. The substrate 202 may have various dimensions, such as 200 or 300 mm diameter wafers, as well as rectangular or square panels. The substrate 202 may comprise a material such as crystalline silicon (e.g., Si<100> or Si<111>), silicon oxide, strained silicon, silicon germanium, doped or undoped polysilicon, doped or undoped silicon wafers, patterned or non-patterned wafers, silicon on insulator (SOD, carbon doped silicon oxides, silicon nitride, doped silicon, germanium, gallium arsenide, glass, sapphire, or the like.

The semiconductor device 200 may be completely or partially formed upon the substrate 202 and includes at least the first layer 204 to be nitridized. The semiconductor device 200 may be, for example, a field effect transistor (FET), DRAM, Flash memory device, or the like. The first layer 204 may be, for example, utilized as a gate dielectric layer of a transistor device, a tunnel oxide layer in a Flash memory device, a spacer layer atop a gate structure, in the inter-poly dielectric (IPD) layer of a Flash memory device, or the like. The first layer 204 may have a thickness from about 1.5 nm to about 20 nm. The first layer may comprise an oxide layer, such as silicon oxide (SiO₂), hafnium oxide (HfO), hafnium silicate (HfSiO₄), or any suitable oxide layer used in a semiconductor device and requiring nitridation. For example, the oxide layer may be a native oxide layer, or formed by any suitable oxidation process including the oxidation process discussed below in FIG. 3. The first layer 204 need not be limited to an oxide layer, and other suitable layers may benefit from the inventive methods disclosed herein. For example, other suitable embodiments of the first layer 204 may include any or all of a metal oxide layer, high-k, or low-k dielectric layers used in semiconductor manufacturing.

Next, at 104, a first process gas may be provided and utilized to form a first plasma. In some embodiments, the first plasma may be a remote plasma. The first process gas includes at least nitrogen. For example, a suitable first process gas may include nitrogen (N₂), ammonia (NH₃), or a combination thereof. Optionally, the first process gas may further include an inert gas, such as argon (Ar), helium (He), krypton (Kr) or the like. In some embodiments, the first process gas comprises nitrogen (N₂) and argon (Ar).

The first process gas may be supplied at a total gas flow from about 10 sccm to about 2000 sccm, or at about 100 sccm. The first process gas may utilize a range of compositions. In some embodiments, the process may include about 50-100% percent N₂ (i.e., N₂ flow of about 10-1000 sccm). In some embodiments, the process gas may include about 1-20 percent NH₃ (i.e., a NH₃ flow of about 5-100 sccm). In some embodiments, the process mixture may include about 30-90 percent inert gas (i.e., an inert gas flow of about 50-1000 sccm). For example, in one specific embodiment, N₂ comprising may be provided at a rate of about 100 sccm, NH₃ may be provided at a rate of about 10 sccm, and an inert gas comprising Ar may be provided at a rate of about 100 sccm.

The first process gas may be introduced into, for example, a remote plasma reactor, such as the remote plasma reactor 500 discussed below to form the first plasma. In embodiments where the first plasma is formed remotely, the first plasma may be formed at a higher plasma density than permitted by conventional in-situ plasma chambers such as an inductively coupled or capacitively coupled plasma chambers. In some embodiments, the plasma density of the first plasma is about 10⁹ to about 10¹⁷ molecules/cm³. The plasma may be formed by using an RF source power. In some embodiments, the RF source power is about 6 kW to about 10 kW. The RF source power may be provided at any suitable RF frequency. For example, in some embodiments, the RF source power may be provided at a frequency of about 2 to about 13.5 MHz.

The first plasma generally comprises ionic species and electrons formed from the disassociation of the first process gas. When formed remotely, during the time it takes the first plasma to reach the semiconductor device 200, the ionic species and the electrons of the first plasma can react to form a first reactive species 206. In some embodiments, the first reactive species may include no ions, or substantially no ions. In some embodiments, the portion of the first plasma that reacts with the substrate may include solely the first reactive species. In some embodiments, the portion of the first plasma that reacts with the substrate may include predominantly the first reactive species (e.g., greater than 50%). The first reactive species 206 may include non-ionic fragments of the first process gas and/or non-ionic molecules, each formed from interactions between the ionic species and electrons of the first remote plasma. For example, when the process gas comprises N₂, and Ar, the reactive species may include N, and Ar* (e.g., an excited state of an argon atom (Ar)), or N* (e.g., an excited state of a nitrogen atom (N) or a nitrogen molecule (N₂)). As described herein, “an excited state” is understood to mean any of the allowed excited states of the atoms or molecules disclosed herein. Thus, the applied power level can be substantially increased without having any energetic ions, which can significantly accelerate the nitridation rate (or oxidation, as discussed below) and improve the tool throughput.

At 106, and depicted in FIG. 2B, the first layer 204 is exposed to the first reactive species 206. In some embodiments, the exposed surface of the substrate 202 may be covered with a sacrificial layer (not shown), such as a masking layer to prevent exposure to the first reactive species 206. The density of the reactive species during the exposure may be about 10⁹ to about 10¹⁷ molecules/cm³. The density of the first reactive species may be measured proximate the substrate, such as immediately above the substrate surface or the plane of the substrate. For example, the density of first reactive species 206 may be about two times or more greater than a radical density typically achievable in conventional plasma nitridation processes. The average radical species may be typically less reactive than the average ionic species (i.e., plasma). Further, when formed remotely, due to remote generation of the first plasma, a chamber pressure during the inventive nitridation process may be about 5 mTorr to about 3 Torr. In some embodiments, a broader pressure range facilitated by remote plasma generation may permit a higher density of reactive species to interact with the first layer 204 than a conventional in-situ plasma reactor may allow. Thus, a higher density of the reactive species may, for example, facilitate sufficient nitridation of the first layer 204, but not excess nitridation as sometimes resultant during conventional plasma nitridation processes. Thus, the higher density and/or lower reactivity of the reactive species may facilitate improved process throughput during nitridation by reducing and/or eliminating the need for a pulsed RF mode having a long duty cycle.

The use of the first reactive species 206 may provide a broader process window for parameters other than chamber pressure as well, allowing for improved nitridation and/or improved process throughput. For example, the substrate can be heated up to much higher temperatures without risking destroying the device features because few or no ions are present. In some embodiments, the substrate 202 and first layer 204 may be heated to a temperature of about 50 to about 700 degrees Celsius. The improved temperature range may facilitate a higher nitridation rate and/or a higher nitrogen content. In some embodiments, at a temperature of about 50 to about 200 degrees Celsius, the nitrogen content incorporated into the first layer 204 may be about 1 to about 25 atomic percent.

The reactive species may further be provided with improved uniformity than possible using conventional in-situ plasma nitridation. For example, conventional plasma nitridation typically requires high RF power to produce a sufficient plasma density for nitridation. Unfortunately, at such power levels the plasma can be non-uniform, and thus nitridation may be non-uniform. By comparison, the first reactive species 206 may not be limited by such non-uniformities.

In some embodiments, the first reactive species 206 may be provided to the first layer 204 at an increased rate by applying an RF bias power to the substrate 202, in addition to the remote plasma generation. In some embodiments, the nitridation process may be performed for a first period of time without RF bias in order to form a seed nitride layer, and the nitridation process may continue for a second period of time with RF bias to enhance the nitridation rate and form a bulk nitride layer. For example, the RF bias power may be applied at low voltage, such as from about 50 to about 500 Volts. The RF bias power may be applied at a frequency range of about 0.3 MHz to about 60 MHz, for example, to limit ion bombardment on the device 200,

At 108, the nitrogen-containing layer 208 may be formed, as shown in FIG. 2C. The nitrogen-containing layer 208 is formed from exposure of the first layer 204 to the first reactive species 206 as discussed above. The nitrogen-containing layer 208 may be, for example, utilized as a gate dielectric layer of a transistor device, a tunnel oxide layer in a Flash memory device, a spacer layer atop a gate structure, in an inter-poly dielectric (IPD) layer of a Flash memory device, or the like. The nitrogen-containing layer 208 may have a thickness of about 10 Angstroms to about 200 Angstroms. The nitrogen-containing layer 208 may have a nitrogen content of about 1 to about 25 atomic percent. The nitrogen-containing layer 208 may comprise an oxynitride layer, such as silicon oxide (SiON), hafnium oxynitride (HfNO), nitride hafnium silicate (n-HfSiO₄), or any suitable oxynitride layer used in a semiconductor device and requiring nitridation. The nitrogen-containing layer 208 need not be limited to an oxynitride layer, and other suitable layers may benefit from the inventive methods disclosed herein. For example, other suitable embodiments of the nitrogen-containing layer 208 may include forming (or enriching N concentration in) titanium nitride (TiN), tantalum nitride (TaN) tungsten nitride (WN), or silicon nitride (SiN) layers. Upon formation of the nitrogen-containing layer 208, the method 100 generally ends and the substrate may be further processed as desired for a particular application.

In some embodiments, a selective oxidation process is also provided. For example, the inventor has discovered that a selective oxidation process can also benefit from a higher density of reactive species as discussed above. FIG. 3 depicts a selective oxidation process 300 in accordance with some embodiments of the present invention. Generally, the process 300 includes providing a partially fabricated semiconductor structure including a substrate having a plurality of film layers (e.g., a film stack) disposed thereon. The semiconductor structure may be a partially fabricated semiconductor device such as Logic, DRAM, or Flash memory devices. Generally, the process 300 further includes forming a remote plasma from a process gas, and exposing the film stack to a reactive species formed from the remote plasma to selectively form an oxide layer. The oxide layer may be selectively formed on non-metal layers of the film stack, for example, a tunnel oxide layer, or a floating gate. However, formation of the oxide layer may be limited on, for example, metal-containing layers of the film stack, such as electrically conductive layers, and the like.

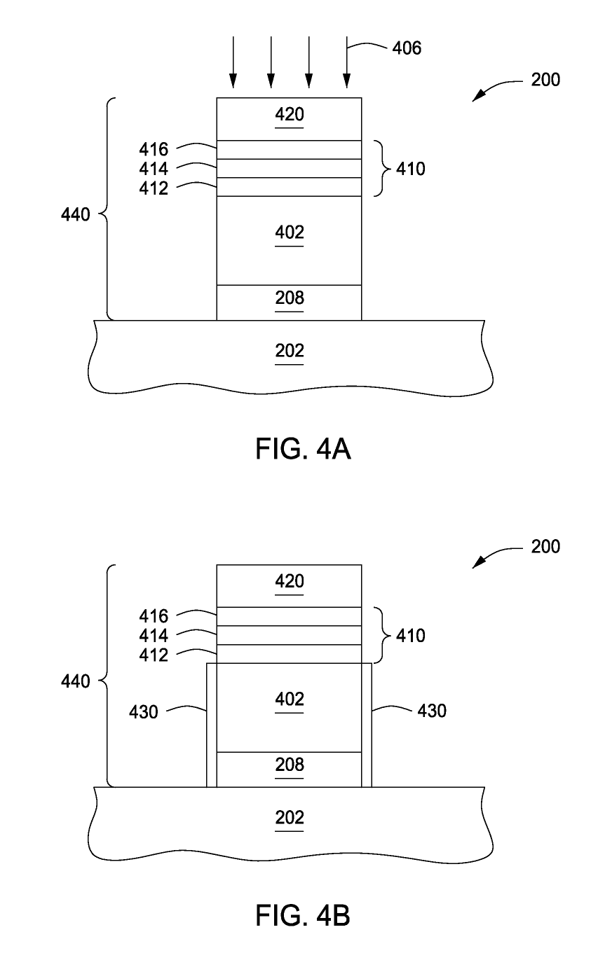

The process 300 is described herein with respect to the semiconductor structure depicted in FIGS. 4A-B, which respectively depict stages of fabrication of a semiconductor structure including a film stack formed on a substrate. The process 300 may be performed, for example, in a toroidal source plasma immersion ion implantation reactor (e.g., a remote plasma reactor) such as the remote plasma reactor depicted in FIG. 3 or other plasma reactor suitable to form a plasma having the characteristics described herein. Similar to the nitridation process 100, the oxidation process 300 may benefit from a broader process window that a remote plasma reactor can provide.

The process 300 begins at 302, where the substrate 202 is provided having a film stack 440 to be oxidized disposed thereupon, as shown in FIG. 4A. The substrate 202 and film stack 440 are one exemplary embodiment of the semiconductor device 200. For example, as depicted in FIGS. 4A-B, the semiconductor device 200 may be a memory device, such as a DRAM memory device. The semiconductor device 200 may be completely or partially formed upon the substrate 202 and includes at least the film stack 440. In some embodiments, as shown in FIG. 4A at 304, the film stack 240 may be formed upon the substrate 202 and then provided to a suitable remote plasma reactor for the oxidation process. For example, one or more process chambers for forming the film stack 240 and a remote plasma reactor may be coupled to a common platform, such as a cluster tool. One example of a suitable cluster tool is a Gate Stack CENTURA®, available from Applied Materials, Inc., of Santa Clara, Calif.

The film stack 440 may be any stack of materials including metal-containing and non-metal containing layers where the non-metal containing layers are to be selectively oxidized. The metal-containing layers may include electrically conductive ceramics partially comprising a metal, or purely comprise one or more metals. The metal-containing layers may include titanium nitride (TiN), tungsten silicon nitride (WSiₓN), tungsten nitride (WN), tantalum carbide (TaC), and tantalum nitride (TaN), titanium (Ti) and tungsten (W). Such a film stack may be part of a dynamic random access memory (DRAM) memory device. Because an oxidation process may cause undesired oxidation of the metal-containing layers, reducing desired properties such as conductivity, a selective oxidation process may be required. Such a selective process would preferentially oxidize at least some of the non-metal containing layers, but cause limited or no oxide layer to form on the metal-containing layers. Hence, the desired properties of the metal-containing layers may be preserved.

For example, in some embodiments, such as in DRAM memory devices, the film stack 440 may be any stack of materials to be oxidized where selective oxidation is desired. In some embodiments, the stack 440 includes the nitrogen-containing layer 208 (i.e., a tunnel oxide layer), a floating gate layer 402, one or more electrically conductive barrier layers 412, 414, at least one metal layer 416 and a capping layer 420. The electrically conductive barrier layers 412, 414, and the metal layer 416 form a metal electrode 410. The one or more electrically conductive barrier layers 412, 414 may include titanium nitride (TiN), tungsten silicon nitride (WSiₓN), tungsten nitride (WN), tantalum carbide (TaC), and tantalum nitride (TaN). The at least one metal layer 416 may include titanium (Ti) and tungsten (W). In some embodiments, the electrically conductive barrier layers 412, 414 are TiN and WN, respectively. In some embodiments, the metal layer 416 is tungsten (W). The floating gate layer 402 comprises a conductive material, such as polysilicon (Si). The capping layer 220 comprises an insulating material, such as silicon nitride (SiN) or silicon oxide (SiO₂).

In some embodiments, the tunnel oxide layer may be the nitrogen-containing layer 208 formed by the nitridation process 100 as discussed above. However, this is merely exemplary, and illustrates how the nitridation process 100 may be utilized with various embodiments of the semiconductor device 200. For example, the barrier layers 412, 414 may additionally benefit from the nitridation process 100. However, the tunnel oxide layer may also be formed by other oxidation processes. Further, the tunnel oxide layer need not be limited to a nitrogen-containing layer, and may alternatively comprise an oxygen-containing material, such as SiO₂, HfO, or the like.

Film stacks in other applications comprising both metal-containing layers and non metal-containing layers may be advantageously oxidized in accordance with the teachings provide herein, wherein an oxide layer may be selectively formed on portions of the gate stack, such as the side walls of the tunnel oxide layer 208, and floating gate layer 402, and wherein the metal-containing layers (for example, the electrically conductive barrier layers 412, 414, and the metal layer 416) remain free of an oxide layer, for example as illustrated in FIG. 2B. Such film stacks may illustratively include Charge Trap Flash (CTF) for Non-volatile Memory (NVM), or the like. Charge Trap Flash (CTF) for Non-volatile Memory (NVM) uses a SiO₂/SiN/Al₂O₃ gate stack with a metal electrode of tantalum nitride (TaN) or titanium nitride (TiN) that may also benefit from sidewall oxidation after gate etch.

Next, at 306, a second process gas may be introduced into a plasma reactor, such as the remote plasma reactor 500 described below in FIG. 3, and utilized to form a second plasma. The second process gas includes at least oxygen. In some embodiments, the second process gas comprises hydrogen (H₂) and oxygen (O₂). In some embodiments, hydrogen (H₂) may be less than about 90 percent, or up to about 75 percent of the total amount of hydrogen (H₂) and oxygen (O₂) provided. In some embodiments, the hydrogen (H₂) may be about 10 to about 80 percent of the total amount of oxygen (O₂) and hydrogen (H₂) provided (e.g., a flow rate ratio of hydrogen (H₂) to oxygen (O₂) about 1:10 to about 4:1). The addition of hydrogen (H₂) to the oxygen (O₂) can increase the thickness of a silicon oxide film by up to about 20 percent, as compared to similar processes using oxygen (O₂) alone.

In some embodiments, the second process gas may be provided at total flow rate of about 100 to about 2000 sccm, or at about 150 sccm. For example, oxygen (O₂) and hydrogen (H₂) may be provided in a total flow rate of about 100 to about 2000 sccm, or at about 150 sccm, in the percentage ranges described above. In some embodiments, the inert gases may be provided as necessary to provide a total flow rate of about 100 to about 2000 sccm. In some embodiments, the inert gases may be provided as necessary to provide a process gas mixture having a content of about 50 percent or higher hydrogen (H₂). In some embodiments, the one or more inert gases may include argon (Ar), helium (He), krypton (Kr), neon (Ne), or the like. The addition or one or more inert gases to the process gas may facilitate higher oxidation rates. In one specific embodiment, oxygen (O₂) is provided at about 30 sccm, hydrogen (H₂) is provided at about 150 sccm, and argon (Ar) is provided at about 20 sccm.

The second process gas may be introduced into a plasma reactor, for example, the remote plasma reactor 500 discussed below to form the second plasma. The second plasma may be formed using the same process parameters as discussed above with respect to the first plasma.

The second plasma generally comprises ionic species and electrons formed from the disassociation of the second process gas. During the time it takes the ionic species and electrons from the second remote plasma to reach the semiconductor device 200, the ionic species and the electrons of the second remote plasma can react to form a second reactive species 406. In some embodiments, the second reactive species may include no ions, or substantially no ions. In some embodiments, the portion of the second plasma that reacts with the substrate may include solely the second reactive species. In some embodiments, the portion of the second plasma that reacts with the substrate may include predominantly the second reactive species (e.g., greater than 50%). The second reactive species 406 may include non-ionic fragments of the second process gas and/or non-ionic molecules, each formed from interactions between the ionic species and electrons of the second remote plasma. For example, when the process gas comprises NH₃, N₂, and Ar, the ion species inside the remote plasma source may include ArH⁺, H⁺, H₃⁺, NH₂⁺, NH₃⁺, NH₂⁺, N₂⁺, and the like. However, when the gas reaches the wafer, at least some of the ionic species will recombine by then and convert into radical reactive species which may include one or more of H, N, N*, Ar*, NH, or NH₂. Thus, the applied power level can be substantially increased without having any energetic ions, which can significantly accelerate the oxidation rate and improve the tool throughput.

At 308, the film stack 440 is exposed to the second reactive species to selectively form an oxide layer 430 on a portion of the film stack 240 (e.g., on non metal-containing layers of the film stack, such as the tunnel oxide layer 208 and the floating gate layer 402), as shown in FIG. 2B. The density of the reactive species during the exposure may be about 10⁹ to about 10¹⁷ molecules/cm³. For example, the density of second reactive species may be about several orders of magnitude (e.g., about 3 to about 6 orders) greater than a plasma density typically utilized in conventional plasma oxidation processes

Similar to the first reactive species 206 as discussed above, the second reactive species may facilitate the use of a broader process window than a plasma allows. For example, in some embodiments, the oxide layer 430 may be formed at a pressure of about 5 mTorr, or about 5 to about 100 mTorr, or up to about 3 Torr. For example, at such pressures an in-situ plasma may damage the device 200 and/or reduce selectivity for the non-metal containing layers.

The substrate 202 may be maintained at higher temperatures to facilitate increased oxidation rate, for example, the temperature of the substrate 202 may be heated to a temperature of about 50 to about 200 degrees Celsius. Higher temperature may increase the diffusion of the second reactive species 406 into the layers of the film stack 440 therefore increasing the oxidation rate. Diffusion of oxygen between the layers of the film stack 440 might be limited, thereby reducing oxygen diffusion related defects, such as bird's beak.

In some embodiments, the substrate 202 may be biased during formation of the oxide layer 430 to control the flux of the second reactive species to the surface of the film stack 440, and, in some embodiments, to control the thickness of the oxide layer formed. In some embodiments, the oxidation process may be performed for a first period of time without RF bias in order to form a bulk oxide layer, and the oxidation process may continue for a second period of time with RF bias to enhance the oxidation rate. In some embodiments, the bias power applied to the substrate 202 is about 100 to about 1000 Watts. In some embodiments, the substrate is not biased during formation of the oxide layer 230

At 310, the oxide layer 430 may be formed on the non-metal containing layers (e.g., the tunnel oxide layer 208 and floating gate 402). In some embodiments, the oxide layer 430 may be grown at a rate of greater than about 30 Angstroms per minute, or up to about 60 Angstroms per minute. The oxide layer 430 may be formed to any suitable thickness. For example, in some embodiments, the oxide layer 430 may be formed to a thickness of about 5 to about 100 Angstroms. The second reactive species may be provided for any suitable duration to form the oxide layer 430 to the desired thickness. In some embodiments, the duration may be about 10 to about 100 seconds. Upon formation of the oxide layer 430, the method 300 generally ends and the substrate may be further processed as desired for a particular application.

Embodiments of the present invention may be performed in toroidal source plasma ion immersion implantation reactor such as, but not limited to, the Applied Materials, Inc., P3i reactor. Such a suitable reactor and its method of operation are set forth in U.S. Pat. No. 7,166,524, assigned to the assignee of the invention, and which is incorporated herein by reference. Other plasma reactors suitable to form a plasma having the characteristics described above may also be utilized.

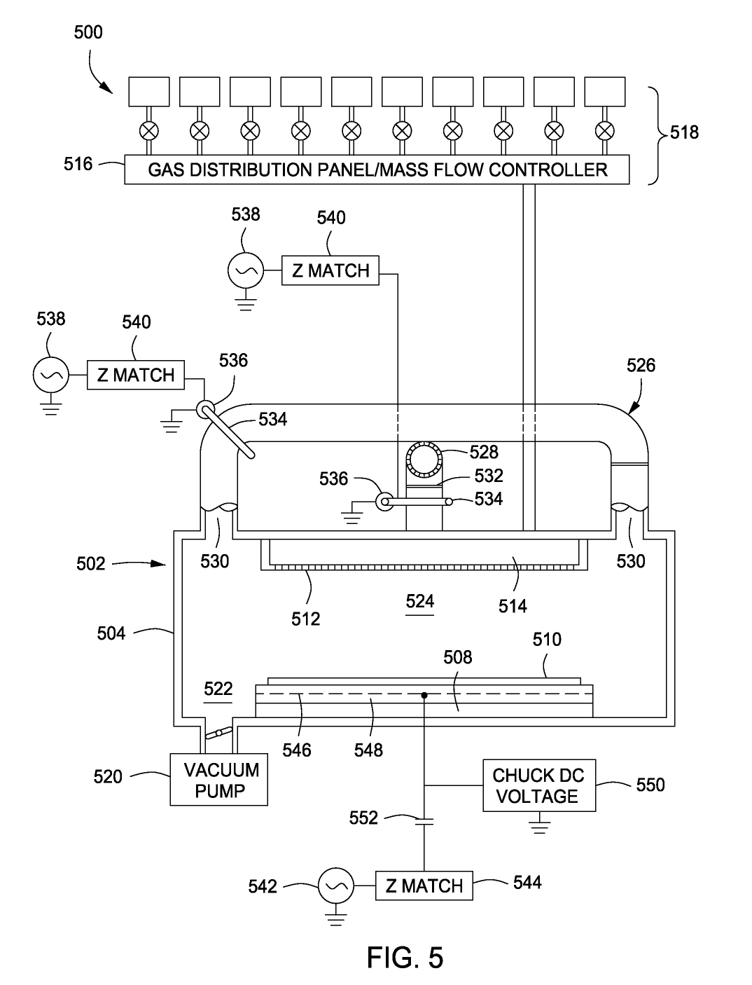

Referring to FIG. 5, a toroidal source plasma immersion ion implantation (“P3i”) reactor 500 of the type disclosed in the above-referenced application has a cylindrical vacuum chamber 502 defined by a cylindrical side wall 504 and a disk-shaped ceiling 506. A substrate support pedestal 508 at the floor of the chamber supports a substrate 510 (e.g., substrate 202 with film stack 440 disposed thereon) to be processed. A gas distribution plate or showerhead 512 on the ceiling 506 receives process gas in its gas manifold 514 from a gas distribution panel 516 whose gas output can be any one of or mixtures of gases from one or more individual gas supplies 518. A vacuum pump 520 is coupled to a pumping annulus 522 defined between the substrate support pedestal 508 and the sidewall 504. A processing region 524 is defined between the substrate 510 and the gas distribution plate 512.

Pair of external reentrant conduits 526, 528 establishes reentrant toroidal paths for plasma currents passing through the processing region 524, the toroidal paths intersecting in the processing region 524. Each of the conduits 526, 528 has a pair of ends 530 coupled to opposite sides of the chamber. Each conduit 526, 528 is a hollow conductive tube. Each conduit 526, 528 has a D.C. insulation ring 532 preventing the formation of a closed loop conductive path between the two ends of the conduit.

An annular portion of each conduit 526, 528, is surrounded by an annular magnetic core 534. An excitation coil 536 surrounding the core 534 is coupled to an RF power source 538 through an impedance match device 540. The two RF power sources 538 coupled to respective ones of the cores 536 may be of two slightly different frequencies. The RF power coupled from the RF power generators 538 produces plasma ion currents in closed toroidal paths extending through the respective conduit 526, 528 and through the processing region 524. These ion currents oscillate at the frequency of the respective RF power source 538. Bias power is applied to the substrate support pedestal 5308 by a bias power generator 542 through an impedance match circuit 544.

Plasma formation and subsequent oxide layer formation is performed by introducing a process gas, or mixture of process gases into the chamber 524 through the gas distribution plate 512 and applying sufficient source power from the generators 538 to the reentrant conduits 526, 528 to create toroidal plasma currents in the conduits and in the processing region 524. The plasma flux proximate the wafer surface is determined by the wafer bias voltage applied by the RF bias power generator 542. The plasma rate or flux (number of ions sampling the wafer surface per square cm per second) is determined by the plasma density, which is controlled by the level of RF power applied by the RF source power generators 538. The cumulative ion dose (ions/square cm) at the wafer 510 is determined by both the flux and the total time over which the flux is maintained.

If the wafer support pedestal 508 is an electrostatic chuck, then a buried electrode 546 is provided within an insulating plate 548 of the wafer support pedestal, and the buried electrode 546 is coupled to the bias power generator 542 through the impedance match circuit 544. A DC chucking voltage is applied to the electrode 546 from a DC chucking voltage source 550 which is isolated from the RF bias power generator 542 by an isolation capacitor 552.

In operation, and for example, the selective formation of an oxide layer on the substrate 510 is achieved by placing the substrate 510 on the substrate support pedestal 508, introducing one or more process gases into the chamber 502 and striking a plasma from the process gases.

In operation, a plasma may be generated from the process gases within the reactor 500 to selectively form an oxide layer on the substrate 510. The plasma is formed in the processing region 524 by applying sufficient source power from the generators 538 to the reentrant conduits 526, 528 to create plasma ion currents in the conduits 526, 528 and in the processing region 524 in accordance with the process described above. In some embodiments, the wafer bias voltage delivered by the RF bias power generator 542 can be adjusted to control the flux of ions to the wafer surface, and possibly the thickness of the oxide layer formed. In some embodiments, no bias power is applied.

Embodiments of the present invention provide methods for nitridation and selective oxidation of semiconductor structures. The inventive processes advantageously provide nitridation and oxidation using reactive species at higher densities, pressures, and temperatures than a plasma process can provide, thereby facilitating increase throughput as compared to traditional in-situ plasma processes.

While the foregoing is directed to embodiments of the present invention, other and further embodiments of the invention may be devised without departing from the basic scope thereof.

1. A method of selectively forming an oxide layer on a semiconductor structure disposed on a substrate support in a process chamber, the semiconductor structure comprising a substrate, one or more metal-containing layers, and one or more non metal-containing layers, the method comprising:
forming a first remote plasma from a first process gas comprising oxygen; and
exposing the semiconductor structure to a reactive species formed from the first remote plasma to selectively form an oxide layer on the one or more non metal-containing layers, wherein a density of the reactive species is about 10⁹ to about 10¹⁷ molecules/cm³ and wherein a pressure in the chamber during exposure of the first layer is about 5 mTorr to about 3 Torr.

2. The method of claim 1, wherein the semiconductor structure further comprises a tunnel oxide layer, a floating gate layer, one or more electrically conductive barrier layers, one or more metal layers, and a capping layer.

3. The method of claim 2, wherein the oxide layer is selectively formed on a side wall of the tunnel oxide layer and the floating gate layer.

4. The method of claim 2, wherein the tunnel oxide layer is formed by a method comprising:
providing the substrate having a first non-metal containing layer disposed thereon;
placing the substrate on the substrate support in the process chamber;
forming a second remote plasma from a second process gas comprising nitrogen; and
exposing the first non-metal layer to a reactive species formed from the second remote plasma to form the tunnel oxide layer, wherein a density of the reactive species is about 10⁹ to about 10¹⁷ molecules/cm³ and wherein a pressure in the chamber during exposure of the first layer is about 5 mTorr to about 3 Torr.

5. The method of claim 4, wherein the first non-metal containing layer is silicon oxide (SiO₂) and the tunnel oxide layer is silicon oxynitride (SiON).

6. The method of claim 4, wherein the tunnel oxide layer comprises silicon oxynitride (SiON), hafnium oxynitride (HfNO), or nitrated hafnium silicate (n-HfSiO₄).

7. The method of claim 4, wherein the first non-metal layer comprises silicon oxide (SiO₂), hafnium oxide (HfO), or hafnium silicate (HfSiO₄).

8. The method of claim 1, wherein the plasma is formed using an RF source power of about 6 kW to about 10 kW.

9. The method of claim 1, further comprising:
heating the substrate to a temperature of about 50 to about 200 degrees Celsius.

10. The method of claim 1, further comprising:
applying an RF bias power to the substrate support at a frequency of about 13.5 MHz to about 60 MHz.

11. The method of claim 1, wherein the first process gas further includes hydrogen and is provided at a flow rate ratio of hydrogen (H₂) to oxygen (O₂) of about 1:10 to about 4:1.

12. The method of claim 11, wherein the first process gas is provided at total flow rate of about 100 to about 2000 sccm.

13. A method of selectively forming an oxide layer on a semiconductor structure disposed on a substrate support in a process chamber, the semiconductor structure comprising a substrate, one or more metal-containing layers, and one or more non metal-containing layers, the method comprising:
forming a first remote plasma from a first process gas consisting essentially of one of oxygen, oxygen and hydrogen, or oxygen, hydrogen, and an inert gas; and
exposing the semiconductor structure to a reactive species formed from the first remote plasma to selectively form an oxide layer on the one or more non metal-containing layers, wherein a density of the reactive species is about 10⁹ to about 10¹⁷ molecules/cm³ and wherein a pressure in the chamber during exposure of the first layer is about 5 mTorr to about 3 Torr.

14. The method of claim 13, wherein the first process gas includes hydrogen and is provided at a flow rate ratio of hydrogen (H₂) to oxygen (O₂) of about 1:10 to about 4:1.

15. The method of claim 13, wherein the first process gas is provided at total flow rate of about 100 to about 2000 sccm.

16. The method of claim 13, wherein the first process gas consists essentially of oxygen, hydrogen, and the inert gas, and wherein the inert gas is one or more of argon (Ar), helium (He), krypton (Kr), or neon (Ne).

17. The method of claim 13, wherein the first process gas consists of oxygen, hydrogen, and the inert gas, and wherein oxygen (O₂) is provided at about 30 sccm, hydrogen (H₂) is provided at about 150 sccm, and argon (Ar) is provided at about 20 sccm.
